(19) United States
(12) Patent Application Publication
(10) Pub. No.: US 2025/0393357 A1
(43) Pub. Date: Dec. 25, 2025

(54) STRETCHABLE DISPLAY DEVICE AND METHOD OF MANUFACTURING THE SAME

(71) Applicant: LG Display Co., Ltd., Seoul (KR)

(72) Inventors: Yu-Ra JEONG, Paju-si (KR); Hae-Yoon JUNG, Paju-si (KR); Ae-Sun KIM, Paju-si (KR); Myung-Sub LIM, Paju-si (KR); In-Jun LEE, Paju-si (KR)

(73) Assignee: LG Display Co., Ltd., Seoul (KR)

(21) Appl. No.: 19/239,623

(22) Filed: Jun. 16, 2025

(30) Foreign Application Priority Data
Jun. 19, 2024 (KR) 10-2024-0079770

(51) Int. Cl. H10H 29/41; H10H 29/01

(52) U.S. Cl. CPC H10H 29/41; H10H 29/012

(57) ABSTRACT

A stretchable display device and a method of manufacturing the same are discussed. The stretchable display device can include a substrate including a rigid area and a soft area, a thin film transistor provided in the rigid area over the substrate, a planarization layer provided over the thin film transistor, a light-emitting element provided over the planarization layer and electrically connected to the thin film transistor, and a stretchable line provided in the soft area over the substrate. The rigid area and the soft area partially overlap each other to thereby form an overlap area, and a distance between adjacent rigid areas is smaller than a length of the soft area.

### CROSS-REFERENCE TO RELATED APPLICATION

The present application claims priority to Korean Patent Application No. 10-2024-0079770, filed in the Republic of Korea on Jun. 19, 2024, the entire contents of which are hereby expressly incorporated by reference into the present application.

### BACKGROUND

### Technical Field

The present disclosure relates to a display device, and more particularly, for example, without limitation, to a stretchable display device and a method of manufacturing the same.

### Discussion of the Related Art

As the information society progresses, interest in displays that process and display a large amount of information has been increasing, and various types of displays have been developed.

Accordingly, in addition to a commonly known rectangular display, flexible display devices such as a bendable display device for gaming, a foldable display device capable of being folded and unfolded, and a rollable display device having optimal space utilization have been widely developed.

Recently, a stretchable display device, which is much more flexible than these flexible display devices, has been in the spotlight as a next-generation display.

The stretchable display device is a display that can freely transform the shape of a screen without distortion even when the size of the screen is increased, folded, or twisted. Unlike the bendable, foldable, or rollable display devices that can only be transformed in a specific area or direction, the stretchable display device is able to implement the ultimate free-form and is considered as the most suitable display for the era of the Internet of Things (IoT), 5G, and autonomous vehicles.

The stretchable display device can include a rigid area in which a pixel is disposed and a soft area in which a connection line connecting the pixels is disposed. The rigid area may not be stretched, and the soft area can be stretched.

Accordingly, in order to secure stretching properties and repeated stretching reliability, sufficient space for the soft area is needed, which limits the increase in the resolution of the stretchable display device.

### SUMMARY OF THE DISCLOSURE

Accordingly, embodiments of the present disclosure are directed to a stretchable display device and a method of manufacturing the same that substantially obviate one or more of the problems due to limitations and disadvantages of the related art.

An aspect of the present disclosure is to provide a stretchable display device with high resolution and a method of manufacturing the same.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, a stretchable display device includes a substrate including a rigid area and a soft area, a thin film transistor provided in the rigid area over the substrate, a planarization layer provided over the thin film transistor, a light-emitting element provided over the planarization layer and electrically connected to the thin film transistor, and a stretchable line provided in the soft area over the substrate, wherein the rigid area and the soft area partially overlap each other to thereby form an overlap area, and a distance between adjacent rigid areas is smaller than a length of the soft area.

In another aspect, a method of manufacturing a stretchable display device includes preparing a carrier substrate on which a rigid area and a soft area are defined, forming a thin film transistor in the rigid area over the carrier substrate, forming a planarization layer over the thin film transistor of the rigid area, forming a stretchable line in the soft area over the carrier substrate, and transferring a light-emitting element over the planarization layer, wherein the light-emitting element is electrically connected to the thin film transistor, wherein the rigid area and the soft area partially overlap each other to thereby form an overlap area, and a distance between adjacent rigid areas is smaller than a length of the soft area.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and which are incorporated in and constitute a part of this application, illustrate embodiments of the disclosure and together with the description serve to explain various principles of the disclosure. In the drawings:

FIG. 1 is a schematic perspective view of a stretchable display device according to embodiments of the present disclosure;

FIG. 2 is a plan view schematically illustrating a part of a stretchable display device according to embodiments of the present disclosure;

FIG. 3 is a plan view schematically illustrating another example of a part of a stretchable display device according to the embodiments of the present disclosure;

FIG. 4 is a plan view schematically illustrating another example of a stretchable line of the stretchable display device according to the embodiments of the present disclosure;

FIG. 5 is a plan view schematically illustrating another example of a part of a stretchable display device according to the embodiments of the present disclosure;

FIG. 6 is an equivalent circuit diagram for a sub-pixel of a stretchable display device according to the embodiments of the present disclosure;

FIG. 7 is a schematic cross-sectional view corresponding to line I-I′ of FIG. 5 according to the embodiments of the present disclosure;

FIG. 8 is a schematic cross-sectional view corresponding to line II-II' of FIG. 5 according to the embodiments of the present disclosure;

FIGS. 9A to 9G are schematic plan views of a stretchable display device in steps of manufacturing the same according to the embodiments of the present disclosure; and

FIGS. 10A to 10G are schematic cross-sectional views of a stretchable display device in steps of manufacturing the same according to the embodiments of the present disclosure.

### DETAILED DESCRIPTION OF THE EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted or can be briefly discussed. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations can be selected only for convenience of writing the specification and can be thus different from those used in actual products.

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Any implementation described herein as an “example” is not necessarily to be construed as preferred or advantageous over other implementations.

The same reference numerals refer to the same components throughout this disclosure.

Further, in the following description of the present disclosure, when a detailed description of a known related art is determined to unnecessarily obscure the gist of the present disclosure, the detailed description thereof will be omitted herein or can be briefly discussed.

When terms such as “including,” “having,” “comprising” and the like mentioned in this disclosure are used, other parts can be added unless the term “only” is used herein.

Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner. For example, the term “in contact with,” as used herein, encompasses both “indirect contact” and “direct contact.” Accordingly, when the phrase “A is in contact with B” is used, it implies that other components can be present between A and B, unless explicitly specified as “A is in direct contact with B.”

Although the terms first, second, and the like are used to describe various components, these components are not substantially limited by these terms. These terms are used only to distinguish one component from another component, and may not define any order or sequence. Therefore, a first component described below can substantially be a second component within the technical idea of the present disclosure.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element. Further, the term “can” fully encompasses all the meanings and coverages of the term “may” and vice versa.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Rather, these embodiments of the present disclosure can be provided so that this disclosure can be sufficiently thorough and complete to assist those skilled in the art to fully understand the scope of the present disclosure. Furthermore, the present disclosure is only defined by scopes of claims.

Features of various embodiments of the present disclosure can be partially or entirely united or combined with each other, technically various interlocking and driving are possible, and each of the embodiments can be independently implemented with respect to each other or implemented together in a related relationship.

Hereinafter, example embodiments of the present disclosure will be described in detail with reference to accompanying drawings. All the components of each display device according to all embodiments of the present disclosure are operatively coupled and configured.

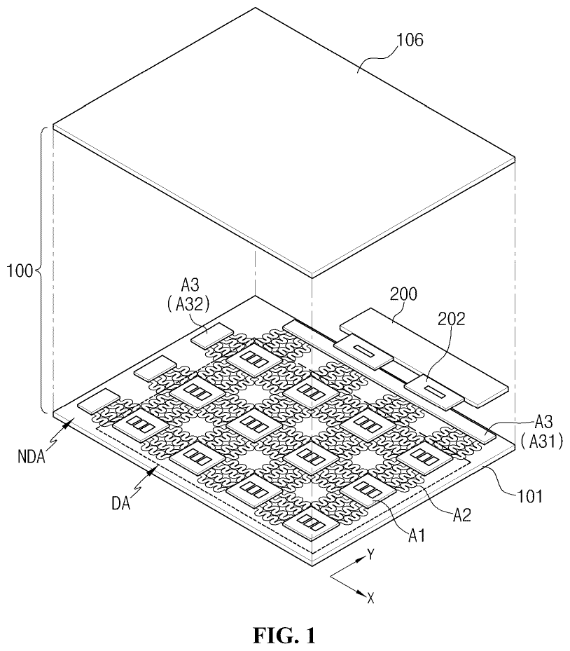

FIG. 1 is a schematic perspective view of a stretchable display device according to embodiments of the present disclosure.

Referring to FIG. 1, the stretchable display device can include a display panel 100, a printed circuit board 200, and a flexible printed circuit 202.

The display panel 100 can be stretched in a first direction (e.g., X) and/or a second direction (e.g., Y). The display panel 100 can include a first substrate 101 and a second substrate 106, and a display area DA displaying an image and a non-display area NDA provided on and surrounding at least one side of the display area DA can be defined on the first substrate 101.

A rigid area A1 corresponding to a first area and a soft area A2 corresponding to a second area can be provided in the display area DA of the first substrate 101, and a pad area A3 corresponding to a third area can be provided in the non-display area NDA of the first substrate 101.

The rigid area A1 can be provided in the form of an island, and a plurality of rigid areas A1 can be disposed to be spaced apart from each other along the first direction X and the second direction Y. The rigid areas A1 can be disposed in a matrix form.

For example, the rigid area A1 can have a polygonal shape, and can have a substantially rectangular shape.

A pixel including a plurality of sub-pixels can be provided in each rigid area A1. Each of the plurality of sub-pixels can include a light-emitting diode, at least one thin film transistor, a plurality of lines, a plurality of electrodes, and a plurality of pads.

The soft area A2 can be disposed between the rigid areas A1 adjacent to each other in each of the first direction X and the second direction Y. Multiple soft areas A2 can be provided between the adjacent rigid areas A1. In addition, the soft area A2 can be disposed between the rigid area A1 and the pad area A3 (e.g., the second pad area A32) adjacent to each other in the first direction X and between the rigid area A1 and the pad area A3 (e.g., the first pad area A31) adjacent to each other in the second direction Y.

A stretchable line that is a connection line connecting the adjacent pixels can be provided in the soft area A2. The stretchable line can include a plurality of voltage lines such as a gate line, a data line, a high potential line, a low potential line, an emission line, and a reference voltage line.

The stretchable line can have at least one curved part. For example, the stretchable line can have a wave structure.

Meanwhile, the non-display area NDA can be an area in which an image is not displayed, and the pad area A3 can be disposed in the non-display area NDA. A plurality of link lines extending from the plurality of voltage lines disposed in the display area DA and a plurality of bonding pads connected to ends of the plurality of link lines can be provided in the pad area A3 of the non-display area NDA.

The pad area A3 can include a first pad area A31 and a second pad area A32. The first pad area A31 can correspond to the rigid areas A1 arranged in the first direction X, and the second pad area A32 can correspond to the rigid areas A1 arranged in the second direction Y. The first pad area A31 can be disposed on at least one of upper and lower sides of the display area DA, and the second pad area A32 can be disposed on at least one of left and right sides of the display area DA. For example, as shown in FIG. 1, the first pad area A31 can be disposed on the upper side of the display area DA, and the second pad area A32 can be disposed on the left side of the display area DA.

The first pad area A31 can be provided as one pattern corresponding to the plurality of rigid areas A1 arranged in the first direction X. That is, the first pad area A31 configured as one rigid pattern can correspond to the plurality of rigid areas A1.

On the other hand, the second pad area A32 can be separated to correspond to each of the plurality of rigid areas A1 arranged in the second direction Y. That is, the second pad areas A32 configured as a plurality of rigid patterns can correspond to the plurality of rigid areas A1, respectively.

However, embodiments of the present disclosure are not limited thereto. In other embodiments, the first pad area A31 can be separated to correspond to each of the plurality of rigid areas A1 arranged in the first direction X, and the second pad area A32 can be provided as one pattern corresponding to the plurality of rigid areas A1 arranged in the second direction Y.

The rigid area A1 and the pad area A3 may not be stretched, and the soft area A2 can be stretched.

Meanwhile, the flexible printed circuit 202 can be connected to the first pad area A31 of the pad area A3. The flexible printed circuit 202 can include a base film made of a flexible material and a driver integrated circuit chip (driver IC chip) mounted on the base film. The flexible printed circuit 202 can generate a gate signal and a data signal for displaying the image and transmit the gate signal and the data signal to the display panel 100.

In the embodiments of FIG. 1, the flexible printed circuit 202 is shown to be a chip on film (COF) type, but embodiments of the present disclosure are not limited thereto. In other embodiments, the flexible printed circuit 202 can be a chip on glass (COG) type or a tape carrier package (TCP) type.

The printed circuit board 200 can include a circuit part for controlling the driver IC chip. For example, the printed circuit board 200 can include a timing controller receiving an image signal and a plurality of timing signals from an external system, generating a plurality of control signals, and transmitting the generated control signals to the driver IC chip.

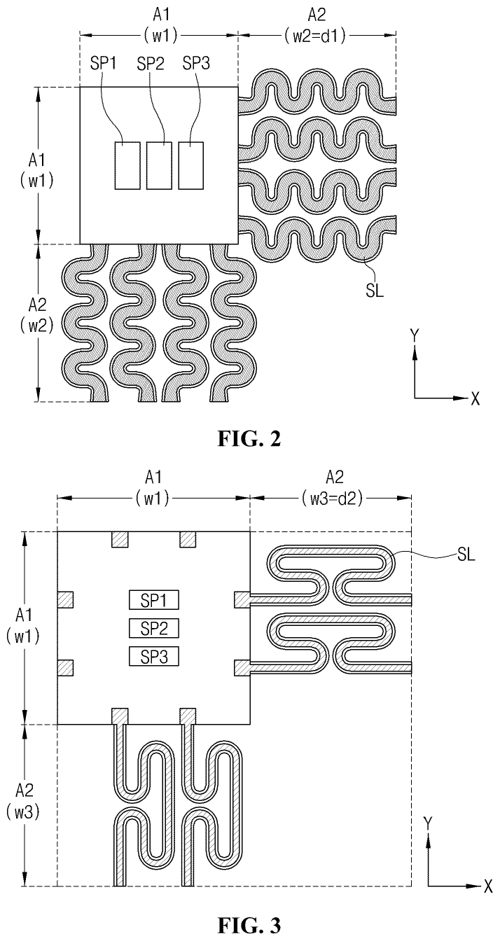

The display area DA of the stretchable display device according to embodiments of the present disclosure will be described in detail with reference to FIG. 2.

FIG. 2 is a plan view schematically illustrating a part of a stretchable display device according to embodiments of the present disclosure.

Referring to FIG. 2, the stretchable display device according to the embodiments of the present disclosure can include the rigid area A1 and the soft area A2 in the display area DA.

In the rigid area A1, a plurality of sub-pixels SP1, SP2, and SP3 can be provided. For example, first, second, and third sub-pixels SP1, SP2, and SP3 can be provided in the rigid area A1, and the first, second, and third sub-pixels SP1, SP2, and SP3 can be red, green, and blue sub-pixels, respectively.

Each of the first, second, and third sub-pixels SP1, SP2, and SP3 can include a light-emitting element, at least one transistor, and at least one capacitor.

In the soft area A2, a stretchable line SL can be provided. The stretchable line SL can include at least one curved part. For example, the stretchable line SL can have a wave structure and can include a plurality of wave shapes. The wave shape can include at least one curved part and at least one straight part, and the straight part can be arranged substantially perpendicular to an extension direction of the stretchable line SL.

Four stretchable lines SL can be disposed between the adjacent rigid areas A1. Two stretchable lines SL can be disposed symmetrically with other two stretchable lines SL.

However, embodiments of the present disclosure are not limited thereto. In other embodiments, the stretchable line SL can have various structures, and the number of stretchable lines SL can vary.

In the stretchable display device according to the embodiments of the present disclosure, the rigid area A1 and the soft area A2 can have substantially the same area. That is, a length or width w1 of the rigid area A1 can be equal to a length or width w2 of the soft area A2. Accordingly, a distance d1 between adjacent rigid areas A1 can be equal to the width w2 of the soft area A2, and can also be equal to the width w1 of the rigid area A1.

For example, the resolution of the stretchable display device according to the embodiments of the present disclosure can be 100 PPI (pixel per inch).

To increase the resolution, the width w2 and area of the soft area A2 can be decreased. However, if the width w2 and area of the soft area A2 are decreased, the stretching properties can be lowered, and thus there are limitations in increasing the resolution.

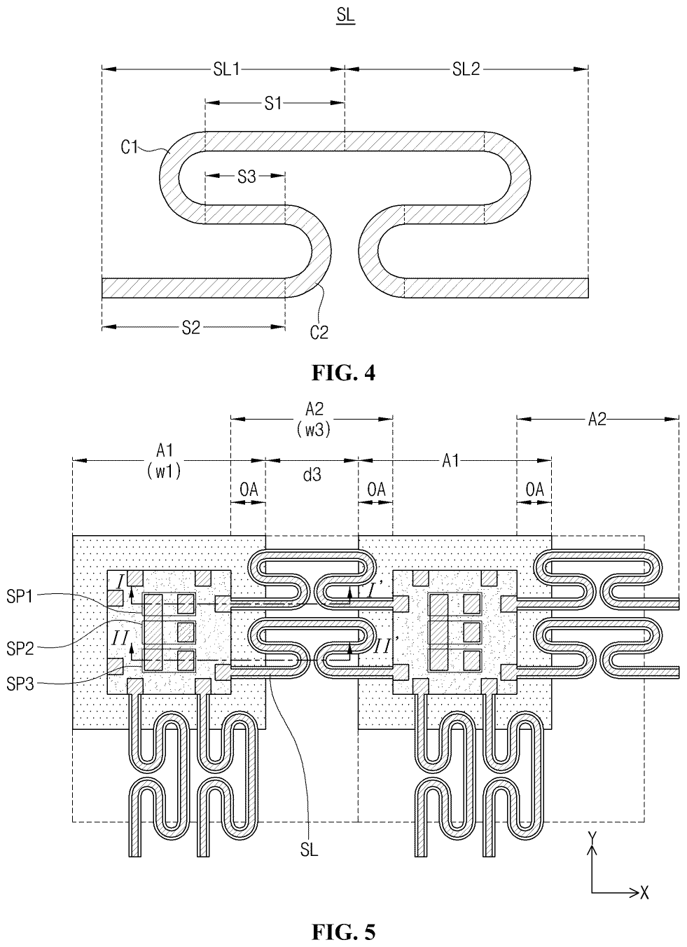

By the way, by changing the structure of the stretchable line, the resolution can be increased without a decrease in the stretchable properties. Such a stretchable display device of another example according to the embodiments of the present disclosure will be described with reference to FIG. 3 and FIG. 4.

FIG. 3 is a plan view schematically illustrating another example of a part of a stretchable display device according to the embodiments of the present disclosure, and FIG. 4 is a plan view schematically illustrating another example of a stretchable line of the stretchable display device according to the embodiments of the present disclosure.

Referring to FIG. 3, the stretchable display device in another example according to the embodiments of the present disclosure can include a rigid area A1 and a soft area A2. A pixel including a plurality of sub-pixels SP1, SP2, and SP3 can be provided in the rigid area A1, and a stretchable line SL connecting adjacent pixels can be provided in the soft area A2.

The stretchable line SL can include at least one curved part. For example, the stretchable line SL can have an omega structure including at least one omega shape. The omega shape can include at least one curved part and at least one straight part, and the straight part can be arranged substantially parallel to an extension direction of the stretchable line SL.

Referring to FIG. 4, the stretchable line SL can include a plurality of line sections SL1 and SL2. Each line section SL1 and SL2 can include at least one straight part S1, S2, and S3 and at least one curved part C1 and C2.

Specifically, the stretchable line SL can include a first line section SL1 and a second line section SL2, and the first line section SL1 and the second line section SL2 can be symmetrical to each other. Each of the first line section SL1 and the second line section SL2 can include first, second, and third straight parts S1, S2, and S3 and first and second curved parts C1 and C2.

The first, second, and third straight parts S1, S2, and S3 can be parallel to each other and can be arranged substantially parallel to the extension direction of the stretchable line SL. The third straight part S3 can be disposed between the first and second straight parts S1 and S2. A length of the first straight part S1 can be greater than a length of the third straight part S3 and smaller than a length of the second straight part S2.

The first curved part C1 can be disposed between the first straight part S1 and the third straight part S3, and the second curved part C2 can be disposed between the second straight part S2 and the third straight part S3. The first and second curved parts C1 and C2 can have substantially the same size and can be arranged convexly in opposite directions.

The first straight parts S1 of the first line section SL1 and the second line section S12 can be connected to each other, and the second straight parts S2 of the first line section SL1 and the second line section SL2 can be connected to respective corresponding rigid areas A1.

However, embodiments of the present disclosure are not limited thereto. In other embodiments, the third straight part S3 can be omitted, and the first and second curved parts C1 and C2 can be directly connected to each other.

The stretchable line SL of the omega structure can have a ratio of length to straight line greater than a stretchable line of a wave structure. The ratio of length to straight line is a value that a total length of the stretchable line is divided by a straight distance between both ends of the stretchable line. As the ratio of length to straight line increases, the elongation rate can increase, and the stretching properties can be high.

In addition, the stretchable line SL of the omega structure can also be deformed in the second direction Y when the stretchable line SL is stretched in the first direction X, thereby contributing to the elongation.

Accordingly, by applying the stretchable line SL of the omega structure having the relatively large ratio of length to straight line, although the straight length of the stretchable line SL, that is, a width w3 of the soft area A2 of FIG. 3 is reduced and smaller than the width w2 of the soft area A2 of FIG. 2, the stretchable properties of the stretchable line SL of the omega structure can be substantially the same as or similar to those of the stretchable line of the wave structure.

In this case, the width w3 and area of the soft area A2 can be smaller than the width w1 and area of the rigid area A1, thereby increasing the resolution of the stretchable display device compared to the stretchable display device of the previous embodiment. The resolution of the stretchable display device of another example according to the embodiments of the present disclosure can be greater than 100 PPI.

Here, a distance d2 between adjacent rigid areas A1 can be equal to the width w3 of the soft area A2 and smaller than the width w1 of the rigid area A1.

As such, the stretchable display device of another example according to the embodiments of the present disclosure can be configured to be provided with the stretchable line SL of the omega structure and to decrease the straight length of the stretchable line SL, thereby increasing the resolution compared to the previous embodiment.

In addition, the rigid area A1 and the soft area A2 can be configured to overlap each other, thereby further increasing the resolution. Such a stretchable display device of another example according to embodiments of the present disclosure will be described with reference to FIG. 5.

FIG. 5 is a plan view schematically illustrating another example of a part of a stretchable display device according to the embodiments of the present disclosure.

Referring to FIG. 5, the stretchable display device in another example according to the embodiments of the present disclosure can include a rigid area A1 and a soft area A2. A pixel including a plurality of sub-pixels SP1, SP2, and SP3 can be provided in the rigid area A1, and a stretchable line SL connecting adjacent pixels can be provided in the soft area A2.

The rigid area A1 and the soft area A2 can partially overlap each other. That is, a part of the stretchable line SL provided in the soft area A2 can also be disposed in the rigid area A1. Accordingly, an overlap area OA of the rigid area A1 and the soft area A2 can be formed, and the part of the stretchable line SL can be disposed in the overlap area OA.

Here, the stretchable line SL can include a plurality of straight parts and a plurality of curved parts. In this case, at least one straight part of the stretchable line SL can be disposed in the overlap area OA.

In addition, at least one curved part of the stretchable line SL can also be disposed in the overlap area OA. In this case, since the stretchable line SL is stretched well, it can be advantageous for elongation.

Alternatively, the plurality of curved parts of the stretchable line SL may not be disposed in the overlap area OA. In this case, since the length of the stretchable line SL is decreased, the resistance of the stretchable line SL can be controlled.

The stretchable line SL can have an omega structure including at least one omega shape. The straight length of the stretchable line SL, that is, the width w3 of the soft area A2 can be smaller than the width w1 of the rigid area A1.

In addition, since the rigid area A1 and the soft area A2 partially overlap each other, a distance d3 between adjacent rigid areas A1 can be smaller than the width w3 of the soft area A2.

As such, the stretchable display device of another example according to the embodiments of the present disclosure can be configured to be provided with the stretchable line SL of the omega structure, to decrease the straight length of the stretchable line SL, and to partially overlap the rigid area A1 and the soft area A2, thereby further increasing the resolution compared to the previous embodiments.

Meanwhile, although the stretchable line SL of the omega structure is described as including one omega shape, embodiments of the present disclosure are not limited thereto. In other embodiments, the stretchable line SL can have an omega structure in which two omega shapes are connected to each other.

Further, it is described that two stretchable lines SL are provided on one side of the rigid area A. However, embodiments of the present disclosure are not limited thereto, and in other embodiments, the number of the stretchable lines SL can vary.

In addition, it is described that the straight length of the stretchable line SL of the omega structure, that is, the width w3 of the soft area A2 is smaller than the width w1 of the rigid area A1, but embodiments of the present disclosure are not limited thereto. In other embodiments, the straight length of the stretchable line SL of the omega structure, that is, the width w3 of the soft area A2 can be equal to the width w1 of the rigid area A1, and since the rigid area A1 and the soft area A2 partially overlap each other, the distance d3 between adjacent rigid areas A1 can be smaller than the width w3 of the soft area A2.

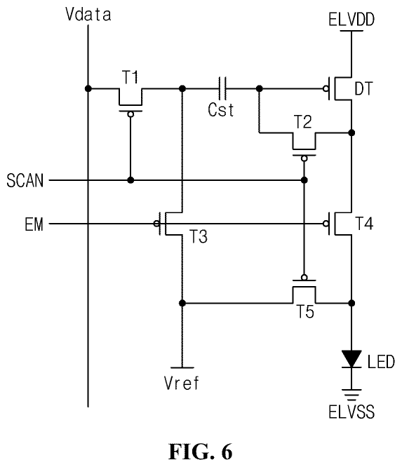

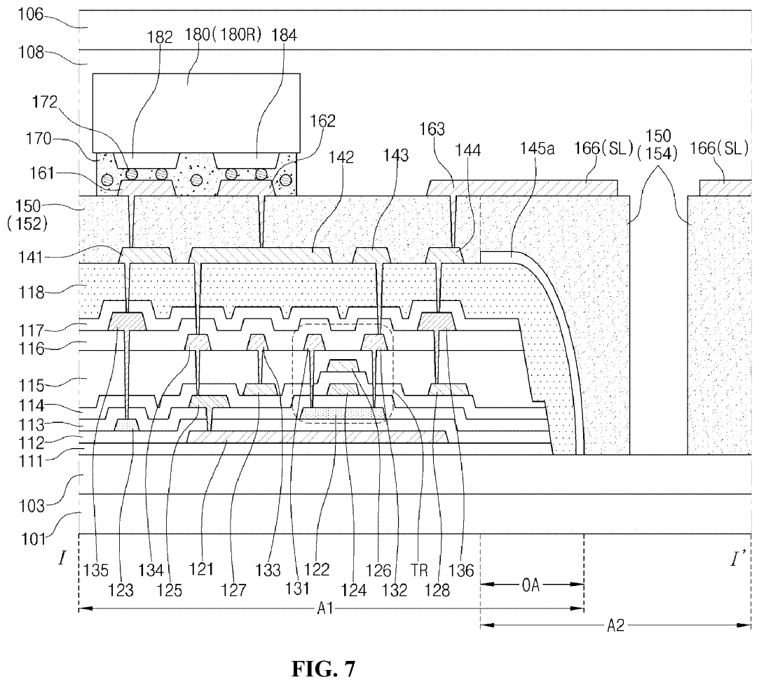

The configuration of the sub-pixel provided in the rigid area A1 of the stretchable display device according to the embodiments of the present disclosure will be described in detail with reference to FIG. 6.

FIG. 6 is an equivalent circuit diagram for a sub-pixel of a stretchable display device according to the embodiments of the present disclosure.

Referring to FIG. 6, one sub-pixel of the stretchable display device according to the embodiments of the present disclosure, that is, each of the first, second, and third sub-pixels SP1, SP2, and SP3 can include a driving transistor DT, first, second, third, fourth, and fifth transistors T1, T2, T3, T4, and T5, a storage capacitor Cst, and a light-emitting diode LED.

For example, the driving transistor DT and the first, second, third, fourth, and fifth transistors T1, T2, T3, T4, and T5 can be P-type transistors. However, embodiments of the present disclosure are not limited thereto. In other embodiments, the driving transistor DT and the first, second, third, fourth, and fifth transistors T1, T2, T3, T4, and T5 can be N-type transistors.

The driving transistor DT can be switched according to a voltage of a first capacitor electrode of the storage capacitor Cst and can be connected to a high potential voltage ELVDD. Specifically, a gate of the driving transistor DT can be connected to the first capacitor electrode of the storage capacitor Cst and a source of the second transistor T2. A source of the driving transistor DT can be connected to the high potential voltage ELVDD. A drain of the driving transistor DT can be connected to a drain of the second transistor T2 and a source of the fourth transistor T4.

The first transistor T1 can be switched according to a gate signal SCAN and can be connected to a data signal Vdata. Specifically, a gate of the first transistor T1 can be connected to the gate signal SCAN. A source of the first transistor T1 can be connected to the data signal Vdata. A drain of the first transistor T1 can be connected to a second capacitor electrode of the storage capacitor Cst and a source of the third transistor T3.

The second transistor T2 can be switched according to the gate signal SCAN and can be connected to the driving transistor DT. Specifically, a gate of the second transistor T2 can be connected to the scan signal SCAN. The source of the second transistor T2 can be connected to the first capacitor electrode of the storage capacitor Cst and the gate of the driving transistor DT. The drain of the second transistor T2 can be connected to the source of the driving transistor DT and the source of the fourth transistor T4.

The third transistor T3 can be switched according to an emission signal EM and can be connected to a reference voltage Vref. A gate of the third transistor T3 can be connected to the emission signal EM. The source of the third transistor T3 can be connected to the second capacitor electrode of the storage capacitor Cst and the drain of the first transistor T1. A drain of the third transistor T3 can be connected to the reference voltage Vref and a source of the fifth transistor T5.

The fourth transistor T4 can be switched according to the emission signal EM and can be connected to the driving transistor DT and the light-emitting diode LED. Specifically, a gate of the fourth transistor T4 can be connected to the emission signal EM. The source of the fourth transistor T4 can be connected to the drain of the driving transistor DT and the drain of the second transistor T2. A drain of the fourth transistor T4 can be connected to a drain of the fifth transistor T5 and a first electrode of the light-emitting diode LED.

The fifth transistor T5 can be switched according to the gate signal SCAN and can be connected to the reference voltage Vref and the fourth transistor T4. Specifically, a gate of the fifth transistor T5 can be connected to the scan signal SCAN. The source of the fifth transistor T5 can be connected to the reference voltage Vref and the drain of the third transistor T3. The drain of the fifth transistor T5 can be connected to the drain of the fourth transistor T4 and the first electrode of the light-emitting diode LED.

The storage capacitor Cst can store the data signal Vdata and a threshold voltage Vth of the driving transistor DT. The first capacitor electrode of the storage capacitor Cst can be connected to the gate of the driving transistor DT and the source of the second transistor T2. The second capacitor electrode of the storage capacitor Cst can be connected to the drain of the first transistor T1 and the source of the third transistor T3.

The light-emitting diode LED can be connected between the fourth and fifth transistors T4 and T5 and a low potential voltage ELVSS and can emit light with luminance proportional to a current of the driving transistor DT. The first electrode of the light-emitting diode LED, which is an anode, can be connected to the drain of the fourth transistor T4 and the drain of the fifth transistor T5. The second electrode of the light-emitting diode LED, which is a cathode, can be connected to the low potential voltage ELVSS.

In the embodiments of the present disclosure of FIG. 6, as an example, each sub-pixel has a 6T1C structure including six transistors and one capacitor, but in other embodiments, each sub-pixel can have one of 2T1C, 3T1C, 3T2C, 4T1C, 4T2C, 5T1C, 5T2C, 6T2C, 7T1C, 7T2C, 8T1C, and 8T2C structures.

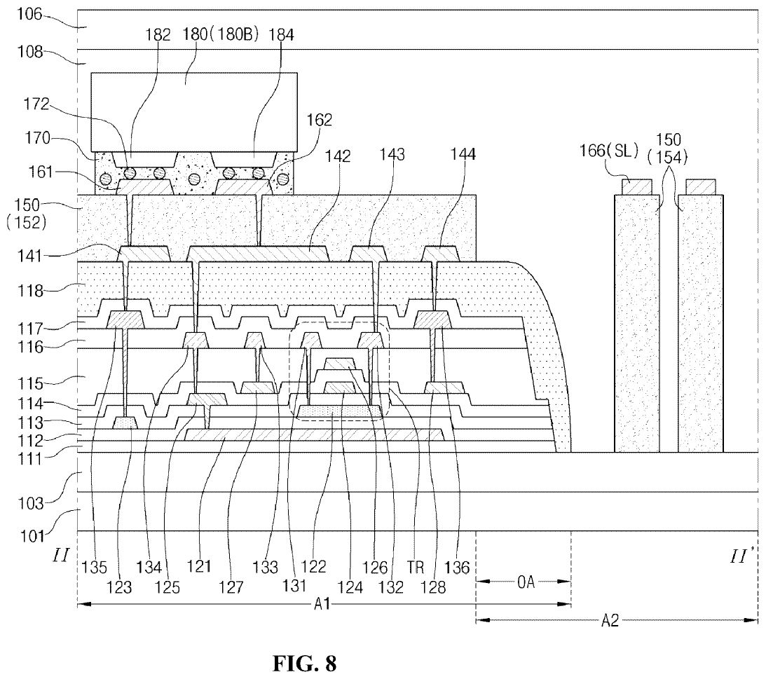

A cross-sectional structure of the stretchable display device according to the embodiments of the present disclosure will be described with reference to FIG. 7 and FIG. 8.

FIG. 7 is a schematic cross-sectional view corresponding to line I-I′ of FIG. 5, and FIG. 8 is a schematic cross-sectional view corresponding to line II-II′ of FIG. 5. Each of FIG. 7 and FIG. 8 shows a cross-section corresponding to one sub-pixel of the stretchable display device according to the embodiments of the present disclosure and will be described with reference to FIG. 5 together.

Referring to FIG. 7 and FIG. 8, the stretchable display device according to the embodiments of the present disclosure can include a first substrate 101 and a second substrate 106 facing and being spaced apart from each other.

The first substrate 101 and the second substrate 106, which are flexible substrates, can be formed of a soft matter or soft material with bending or stretching properties. For example, the first substrate 101 and the second substrate 106 can be formed of silicone rubber such as polydimethylsiloxane (PDMS), elastomer such as polyurethane (PU), or styrene butadiene block copolymer such as styrene butadiene styrene (SBS).

The first substrate 101 and the second substrate 106 can be formed of the same material. However, embodiments of the present disclosure are not limited thereto. In other embodiments, the first substrate 101 and the second substrate 106 can be formed of different materials.

The first substrate 101 and the second substrate 106 can have relatively low elastic modulus, that is, Young's modulus, and can have a relatively high ductile breaking rate. Here, the elastic modulus is a value representing the rate of deformation relative to the stress applied to an object. If the elastic modulus is relatively high, the hardness can be relatively high. In addition, the ductile breaking rate refers to the elongation rate at the point when the stretched object is broken or cracked.

For example, each of the first substrate 101 and the second substrate 106 can have the elastic modulus of several MPa to hundreds of MPa and the ductile breaking rate of about 100% or more. In addition, each of the first substrate 101 and the second substrate 106 can have a thickness of about 10 μm to about 1 mm. However, embodiments of the present disclosure are not limited thereto.

A rigid area A1 corresponding to a first area and a soft area A2 corresponding to a second area can be provided on the first substrate 101 and the second substrate 106. The rigid area A1 and the soft area A2 can partially overlap each other, and an area where the rigid area A1 and the soft area A2 can become an overlap area OA.

A first adhesive layer 103 can be provided on the first substrate 101. The first adhesive layer 103 can be formed of an acryl-based, silicone-based, or urethane-based adhesive. For example, the first adhesive layer 103 can be optically clear adhesive (OCA) that is formed and attached in the form of a film or optically clear resin (OCR) that is cured after applying a liquid material. Meanwhile, in other embodiments, the first adhesive layer 103 can be included in an inner surface of first substrate 101, and in another embodiments, the first adhesive layer 103 can be omitted.

A first buffer layer 111 of a first insulation layer can be provided on the first substrate 101 and the first adhesive layer 103. The first buffer layer 111 can block permeation of moisture or oxygen from the outside to protect the components of the plurality of sub-pixels SP1, SP2, and SP3.

The first buffer layer 111 can be formed as a single layer or multiple layers of an inorganic insulating material. The inorganic insulating material of the first buffer layer 111 can include silicon nitride (SiNx), silicon oxide (SiOx), or silicon oxynitride (SiON).

In order to prevent or reduce damage of the first buffer layer 111 such as cracks due to stretching, the first buffer layer 111 can be provided to substantially correspond to the rigid area A1. In this case, the first buffer layer 111 can be removed in the soft area A2 except for the overlap area OA. Accordingly, a top surface of the first adhesive layer 103 can be exposed in the soft area A2 except for the overlap area OA.

Alternatively, in other embodiments, the first buffer layer 111 can be omitted.

A light blocking layer 121 can be provided on the first buffer layer 111 of the rigid area A1. The light blocking layer 121 can be formed of a conductive material such as metal. For example, the light blocking layer 121 can be formed of at least one of aluminum (Al), copper (Cu), molybdenum (Mo), titanium (Ti), chromium (Cr), nickel (Ni), tungsten (W), or an alloy thereof. The light blocking layer 121 can have a single-layered structure or a multiple-layered structure.

A second buffer layer 112 of a second insulation layer can be provided on the light blocking layer 121 of the rigid area A1. The second buffer layer 112 can be formed as a single layer or multiple layers of an inorganic insulating material. The inorganic insulating material of the second buffer layer 112 can include silicon nitride (SiNx), silicon oxide (SiOx), or silicon oxynitride (SiON).

In order to prevent or reduce damage of the second buffer layer 112 such as cracks due to stretching, the second buffer layer 112 can be provided to substantially correspond to the rigid area A1. In this case, the second buffer layer 112 can be removed in the soft area A2 except for the overlap area OA.

A semiconductor layer 122 can be provided on the second buffer layer 112 of the rigid potion A1. The semiconductor layer 122 can overlap the light blocking layer 121, and the light blocking layer 121 can block light incident on the semiconductor layer 122 and prevent or reduce the semiconductor layer 122 from deteriorating due to the light.

The semiconductor layer 122 can include a channel region at its central part and source and drain regions at both sides of the channel region.

The semiconductor layer 122 can be formed of an oxide semiconductor material. Alternatively, the semiconductor layer 122 can be formed of polycrystalline silicon, and in this case, both ends of the semiconductor layer 122 can be doped with impurities.

In addition, a semiconductor pattern 123 can be further provided on the second buffer layer 112 of the rigid potion A1. The semiconductor pattern 123 can be formed of the same material as the semiconductor layer 122 and can be spaced apart from the light blocking layer 121.

A gate insulation layer 113 of a third insulation layer can be provided on the semiconductor layer 122 and the semiconductor pattern 123 of the rigid area A1. The gate insulation layer 113 can be formed as a single layer or multiple layers of an inorganic insulating material. The inorganic insulating material of the gate insulation layer 113 can include silicon nitride (SiNx), silicon oxide (SiOx), or silicon oxynitride (SiON).

In order to prevent or reduce damage of the gate insulation layer 113 such as cracks due to stretching, the gate insulation layer 113 can be provided to substantially correspond to the rigid area A1. In this case, the gate insulation layer 113 can be removed in the soft area A2 except for the overlap area OA.

A gate electrode 124 and a first conductive pattern 125 can be provided on the gate insulation layer 113 of the rigid area A1.

The gate electrode 124 can overlap the semiconductor layer 122 and can be disposed to correspond to the central part of the semiconductor layer 122. Accordingly, the gate electrode 124 can also overlap the light blocking layer 121.

The first conductive pattern 125 can be spaced apart from the semiconductor layer 122 and the semiconductor pattern 123, and can overlap the light blocking layer 121. The first conductive pattern 125 can be in contact with the light blocking layer 121 through a contact hole provided in the second buffer layer 112 and the gate insulation layer 113.

The gate electrode 124 and the first conductive pattern 125 can be formed of a conductive material such as metal. For example, the gate electrode 124 and the first conductive pattern 125 can be formed of at least one of aluminum (Al), copper (Cu), molybdenum (Mo), titanium (Ti), chromium (Cr), nickel (Ni), tungsten (W), or an alloy thereof. The gate electrode 124 and the first conductive pattern 125 can have a single-layered structure or a multiple-layered structure.

A first interlayer insulation layer 114 of a fourth insulation layer can be provided on the gate electrode 124 and the first conductive pattern 125 of the rigid area A1. The first interlayer insulation layer 114 can be formed as a single layer or multiple layers of an inorganic insulating material. The inorganic insulating material of the first interlayer insulation layer 114 can include silicon nitride (SiNx), silicon oxide (SiOx), or silicon oxynitride (SiON).

In order to prevent or reduce damage of the first interlayer insulation layer 114 such as cracks due to stretching, the first interlayer insulation layer 114 can be provided to substantially correspond to the rigid area A1. In this case, the first interlayer insulation layer 114 can be removed in the soft area A2 except for the overlap area OA.

A second conductive pattern 126, a third conductive pattern 127, and a fourth conductive pattern 128 can be provided on the first interlayer insulation layer 114 of the rigid area A1.

The second conductive pattern 126 can overlap the gate electrode 124, the semiconductor layer 122, and the light blocking layer 121. The third conductive pattern 127 can overlap the light blocking layer 121 and can be spaced apart from the semiconductor layer 122, the gate electrode 124, the first conductive pattern 125, and the second conductive pattern 126. The fourth conductive pattern 128 can partially overlap the light blocking layer 121 and can be spaced apart from the semiconductor layer 122, the gate electrode 124, the first conductive pattern 125, the second conductive pattern 126, and the third conductive pattern 127. However, embodiments of the present disclosure are not limited thereto. In other embodiments, the fourth conductive pattern 128 can be spaced apart from the light blocking layer 121.

The second conductive pattern 126, the third conductive pattern 127, and the fourth conductive pattern 128 can be formed of a conductive material such as metal. For example, the second conductive pattern 126, the third conductive pattern 127, and the fourth conductive pattern 128 can be formed of at least one of aluminum (Al), copper (Cu), molybdenum (Mo), titanium (Ti), chromium (Cr), nickel (Ni), tungsten (W), or an alloy thereof. The second conductive pattern 126, the third conductive pattern 127, and the fourth conductive pattern 128 can have a single-layered structure or a multiple-layered structure.

A second interlayer insulation layer 115 of a fifth insulation layer can be provided on the second conductive pattern 126, the third conductive pattern 127, and the fourth conductive pattern 128 of the rigid area Al. The second interlayer insulation layer 115 can be formed as a single layer or multiple layers of an inorganic insulating material. The inorganic insulating material of the second interlayer insulation layer 115 can include silicon nitride (SiNx), silicon oxide (SiOx), or silicon oxynitride (SiON).

In order to prevent or reduce damage of the second interlayer insulation layer 115 such as cracks due to stretching, the second interlayer insulation layer 115 can be provided to substantially correspond to the rigid area A1. In this case, the second interlayer insulation layer 115 can be removed in the soft area A2 except for the overlap area OA.

A source electrode 131, a drain electrode 132, a fifth conductive pattern 133, and a sixth conductive pattern 134 can be provided on the second interlayer insulation layer 115.

The source electrode 131 and the drain electrode 132 can be spaced apart from each other with the gate electrode 124 positioned therebetween and can be in contact with both ends of the semiconductor layer 122 through contact holes provided in the first and second interlayer insulation layers 114 and 115 and the gate insulation layer 113.

The semiconductor layer 122, the gate electrode 124, the source electrode 131, and the drain electrode 132 can constitute a thin film transistor TR.

The fifth conductive pattern 133 can be spaced apart from the thin film transistor TR. The fifth conductive pattern 133 can overlap the third conductive pattern 127 and the light blocking layer 121 and can be in contact with the third conductive pattern 127 through a contact hole provided in the second interlayer insulation layer 115.

The sixth conductive pattern 134 can be spaced apart from the thin film transistor TR, the semiconductor pattern 123, and the third conductive pattern 127. The sixth conductive pattern 134 can overlap the first conductive pattern 125 and the light blocking layer 121 and can be in contact with the first conductive pattern 125 through a contact hole formed in the first and second interlayer insulation layers 114 and 115.

The source electrode 131, the drain electrode 132, the fifth conductive pattern 133, and the sixth conductive pattern 134 can be formed of a conductive material such as metal. For example, the source electrode 131, the drain electrode 132, the fifth conductive pattern 133, and the sixth conductive pattern 134 can be formed of at least one of aluminum (Al), copper (Cu), molybdenum (Mo), titanium (Ti), chromium (Cr), nickel (Ni), tungsten (W), or an alloy thereof. The source electrode 131, the drain electrode 132, the fifth conductive pattern 133, and the sixth conductive pattern 134 can have a single-layered structure or a multiple-layered structure.

Next, a third interlayer insulation layer 116 of a sixth insulation layer can be provided on the source electrode 131, the drain electrode 132, the fifth conductive pattern 133, and the sixth conductive pattern 134 of the rigid area A1. The third interlayer insulation layer 116 can be formed as a single layer or multiple layers of an inorganic insulating material. The inorganic insulating material of the third interlayer insulation layer 116 can include silicon nitride (SiNx), silicon oxide (SiOx), or silicon oxynitride (SiON).

In order to prevent or reduce damage of the third interlayer insulation layer 116 such as cracks due to stretching, the third interlayer insulation layer 116 can be provided to substantially correspond to the rigid area A1. In this case, the third interlayer insulation layer 116 can be removed in the soft area A2 except for the overlap area OA.

A seventh conductive pattern 135 and an eighth conductive pattern 136 can be provided on the third interlayer insulation layer 116 of the rigid area A1.

The seventh conductive pattern 135 can be spaced apart from the light blocking layer 121 and can overlap the semiconductor pattern 123. The seventh conductive pattern 135 can be in contact with the semiconductor pattern 123 through a contact hole provided in the first, second and third interlayer insulation layers 114, 115, and 116 and the gate insulation layer 113.

The eighth conductive pattern 136 can be spaced apart from the thin film transistor TR and can overlap the fourth conductive pattern 128. The eighth conductive pattern 136 can be in contact with the fourth conductive pattern 128 through a contact hole provided in the second and third interlayer insulation layers 115 and 116.

The seventh conductive pattern 135 and the eighth conductive pattern 136 can be formed of a conductive material such as metal. For example, the seventh conductive pattern 135 and the eighth conductive pattern 136 can be formed of at least one of aluminum (Al), copper (Cu), molybdenum (Mo), titanium (Ti), chromium (Cr), nickel (Ni), tungsten (W), or an alloy thereof. The seventh conductive pattern 135 and the eighth conductive pattern 136 can have a single-layered structure or a multiple-layered structure.

A passivation layer 117 can be provided on the seventh conductive pattern 135 and the eighth conductive pattern 136 of the rigid area A1.

The passivation layer 117 can be formed as a single layer or multiple layers of an inorganic insulating material. The inorganic insulating material of the passivation layer 117 can include silicon nitride (SiNx), silicon oxide (SiOx), or silicon oxynitride (SiON).

In order to prevent or reduce damage of the passivation layer 117 such as cracks due to stretching, the passivation layer 117 can be provided to substantially correspond to the rigid area A1. In this case, the passivation layer 117 can be removed in the soft area A2 except for the overlap area OA.

The passivation layer 117 can be omitted.

A planarization layer 118 can be provided on the passivation layer 117 of the rigid area A1. The planarization layer 118 can eliminate a step difference due to the layers thereunder and can have a substantially flat top surface. The planarization layer 118 can be formed of an organic insulating material such as photosensitive acrylic polymer (photo acryl).

The planarization layer 118 can be provided to substantially correspond to the rigid area A1. In this case, the planarization layer 118 can be removed in the soft area A2 except for the overlap area OA. In the overlap area OA, the planarization layer 118 can be in contact with side surfaces of the first and second buffer layers 111 and 112, the gate insulation layer 113, the first, second, and third interlayer insulation layers 114, 115, and 116, and the passivation layer 117.

A first connection electrode 141, a second connection electrode 142, a ninth conductive pattern 143, and a pad electrode 144 can be provided on the planarization layer 118 of the rigid area A1.

The first connection electrode 141, the second connection electrode 142, the ninth conductive pattern 143, and the pad electrode 144 can be formed of a conductive material such as metal. For example, the first connection electrode 141, the second connection electrode 142, the ninth conductive pattern 143, and the pad electrode 144 can be formed of at least one of aluminum (Al), copper (Cu), molybdenum (Mo), titanium (Ti), chromium (Cr), nickel (Ni), tungsten (W), or an alloy thereof. The first connection electrode 141, the second connection electrode 142, the ninth conductive pattern 143, and the pad electrode 144 can have a single-layered structure or a multiple-layered structure.

The first connection electrode 141 can overlap the seventh conductive pattern 135 and can be in contact with the seventh conductive pattern 135 through a contact hole provided in the planarization layer 118 and the passivation layer 117.

The second connection electrode 142 can overlap the sixth conductive pattern 134 and can be in contact with the sixth conductive pattern 134 through a contact hole provided in the planarization layer 118, the passivation layer 117, and the third interlayer insulation layer 116. In addition, the second connection electrode 142 can overlap the source electrode 131 and the fifth conductive pattern 133 and can be spaced apart from the drain electrode 132.

The ninth conductive pattern 143 can overlap the drain electrode 132 and can be in contact with the drain electrode 132 through a contact hole provided in the planarization layer 118, the passivation layer 117, and the third interlayer insulation layer 116.

The pad electrode 144 can overlap the eighth conductive pattern 136 and can be in contact with the eighth conductive pattern 136 through a contact hole provided in the planarization layer 118 and the passivation layer 117.

Each of the first, second, third, fourth, fifth, sixth, seventh, eighth, and ninth conductive patterns 125, 126, 127, 128, 133, 134, 135, 136, and 143 can be a part of a signal line, an electrode, or a pad.

Next, a protection layer 150 can be provided on the first connection electrode 141, the second connection electrode 142, the ninth conductive pattern 143, and the pad electrode 144. The protection layer 150 can be formed of an insulating material, which is a rigid material having lower flexibility than the soft material of the first substrate 101. For example, the protection layer 150 can be formed of a polyimide (PI) resin or epoxy resin.

The protection layer 150 can have relatively high elastic modulus, and the elastic modulus of the protection layer 150 can be higher than the elastic modulus of the first substrate 101. For example, the elastic modulus of the protection layer 150 can be more than 1,000 times higher than the elastic modulus of the first substrate 101, but embodiments of the present disclosure are not limited thereto.

The protection layer 150 can include a first portion 152 and a second portion 154. The first portion 152 can correspond to the rigid area A1, and the second portion 154 can correspond to the soft area A2. In this case, the first portion 152 can correspond to the rigid area A1 except for the overlap area OA, and the second portion 154 can correspond to the soft area A2 including the overlap area OA.

The first portion 152 of the protection layer 150 can be in contact with the top surface of the planarization layer 118 in the rigid area A1, and the second portion 154 of the protection layer 150 can be in contact with the top surface of the first adhesive layer 103 in the soft area A2. In a plan view, the first portion 152 can have a substantially rectangular shape, and the second portion 154 can have an omega structure. However, embodiments of the present disclosure are not limited thereto. In other embodiments, the first portion 152 can have a circular shape or a polygonal shape except for the rectangular shape, and the second portion 154 can have a wave structure.

Meanwhile, in the overlap area OA, a gap or void 145a can be provided between the planarization layer 118 and the protection layer 150. The void 145a can be provided along top and side surfaces of the planarization layer 118. The second portion 154 of the protection layer 150 can be separated from the planarization layer 118 by the void 145a.

Next, a first electrode 161, a second electrode 162, an auxiliary pad 163, and a stretchable line 166 can be provided on the protection layer 150.

The first electrode 161, the second electrode 162, and the auxiliary pad 163 can be provided in the rigid area A1 and can be spaced apart from the soft area A2. Accordingly, the first electrode 161, the second electrode 162, and the auxiliary pad 163 may not be provided in the overlap area OA. The first electrode 161, the second electrode 162, and the auxiliary pad 163 can be disposed on the first portion 152 of the protection layer 150.

The first electrode 161 can overlap the first connection electrode 141 and can be in contact with the first connection electrode 141 through a contact hole provided in the protection layer 150. The second electrode 162 can overlap the second connection electrode 142 and can be in contact with the second connection electrode 142 through a contact hole provided in the protection layer 150.

The auxiliary pad 163 can be disposed in the rigid area A1 and can be connected to one end of the stretchable line 166. The auxiliary pad 163 can overlap the pad electrode 144 and can be in contact with a contact hole provided in the protection layer 150.

The stretchable line 166 can be provided in the soft area A2 and can also be provided in the overlap area OA. The stretchable line 166 can be connected to the auxiliary pad 163 and can be formed as one body. The stretchable line 166 can be disposed on the second portion 154 of the protection layer 150.

The stretchable line 166 can have substantially the same shape as the second portion 154 of the protection layer 150 and can include at least one straight part and at least one curved part. For example, the stretchable line 166 and the second portion 154 of the protection layer 150 can have an omega structure and can include at least one omega shape. However, embodiments of the present disclosure are not limited thereto. In other embodiments, the stretchable line 166 and the second portion 154 of the protection layer 150 can have a wave structure. Here, in a plan view, a width of the second portion 154 of the protection layer 150 can be greater than a width of the stretchable line 166.

The first electrode 161, the second electrode 162, the auxiliary pad 163, and the stretchable line 166 can be formed of a conductive material such as metal. For example, the first electrode 161, the second electrode 162, the auxiliary pad 163, and the stretchable line 166 can be formed of at least one of aluminum (Al), copper (Cu), molybdenum (Mo), titanium (Ti), chromium (Cr), nickel (Ni), tungsten (W), or an alloy thereof. The first electrode 161, the second electrode 162, the auxiliary pad 163, and the stretchable line 166 can have a single-layered structure or a multiple-layered structure.

Meanwhile, a bank layer can be further provided on the first electrode 161 and the second electrode 162 in the rigid area a1. The bank layer can expose at least parts of the first electrode 161 and the second electrode 162.

Next, an adhesive layer 170 can be provided on the first electrode 161 and the second electrode 162 of the rigid area A1. The adhesive layer 170 can cover and be in contact with the first electrode 161 and the second electrode 162 and can be spaced apart from the auxiliary pad 163 and the stretchable line 166.

The adhesive layer 170 can be an anisotropic conductive film (ACF) including an insulating base member and a plurality of conductive balls 172 dispersed in the insulating base member. When heat or pressure is applied to the adhesive layer 170, in an area where the heat or pressure is applied, the conductive balls 172 can be electrically connected, so that the adhesive layer 170 can have a conductive property, and in an area where the heat or pressure is not applied, the adhesive layer 170 can have an insulating property.

A light-emitting element 180 can be provided on the adhesive layer 170. For example, a red light-emitting element 180R can be provided to correspond to the first sub-pixel SP1, a green light-emitting element can be provided to correspond to the second sub-pixel SP2, and a blue light-emitting element 180B can be provided to correspond to the third sub-pixel SP3,

The light-emitting element 180 can include a first element electrode 182 and a second element electrode 184. Here, the first element electrode 182 can be a p-electrode, and the second element electrode 184 can be an n-electrode. The first element electrode 182 can be an anode, and the second element electrode 184 can be a cathode. However, embodiments of the present disclosure are not limited thereto.

Alternatively, in other embodiments, the first element electrode 182 can be an n-electrode, and the second element electrode 184 can be a p-electrode. In this case, the first element electrode 182 can be a cathode, and the second element electrode 184 can be an anode.

The light-emitting element 180 can be provided in the form of a micro light-emitting diode chip (micro LED chip or uLED chip) including the n-electrode, an n-type layer, an active layer, a p-type layer, and the p-electrode. The light-emitting element 180 can have a flip-chip structure in which the n-electrode and the p-electrode are provided on the same side (for example, a side facing the first substrate 101) and light is emitted through a side opposite to the side provided with the n-electrode and the p-electrode (for example, a side facing the second substrate 106).

However, embodiments of the present disclosure are not limited thereto. The light-emitting element 180 can have a lateral structure in which the n-electrode and the p-electrode are provided on the same side and light is emitted through the same side provided with the n-electrode and the p-electrode or can have a vertical structure in which the n-electrode and the p-electrode are provided on opposite sides, respectively.

The first element electrode 182 of the light-emitting element 180 can overlap the first electrode 161, and the second element electrode 184 of the light-emitting element 180 can overlap the second electrode 162. The first element electrode 182 can be electrically connected to the first electrode 161 through the conductive balls 172 of the adhesive layer 170, and the second element electrode 184 can be electrically connected to the second electrode 162 through the conductive balls 172 of the adhesive layer 170.

Next, a second adhesive layer 108 can be provided on the light-emitting element 180 and the stretchable line 166, and the second substrate 106 can be disposed on the second adhesive layer 108.

The second adhesive layer 108 can attach the light-emitting element 180 and the stretchable line 166 with the second substrate 106. The second adhesive layer 108 can be formed of the same material as the first adhesive layer 103.

However, embodiments of the present disclosure are not limited thereto. In other embodiments, the second adhesive layer 108 can be formed of a different material from the first adhesive layer 103. A thickness of the second adhesive layer 108 can be substantially equal to a thickness of the first adhesive layer 103.

As such, in the stretchable display device according to the embodiments of the present disclosure, the rigid area A1 and the soft area A2 can be configured to partially overlap each other, thereby further increasing the resolution.

At this time, in the overlap area OA of the rigid area A1 and the soft area A2, the void 145a can be provided between the planarization layer 118 and the stretchable line 166, specifically, between the planarization layer 118 and the second portion 154 of the protection layer 150, so that the stretchable line 166 can be separated from the rigid area A1 and stretched.

Meanwhile, the cross-sectional structure of the stretchable display device according to the embodiments of the present disclosure is not limited thereto, and it is possible to vary the location and connection relationship of the patterns provided under the protection layer 150.

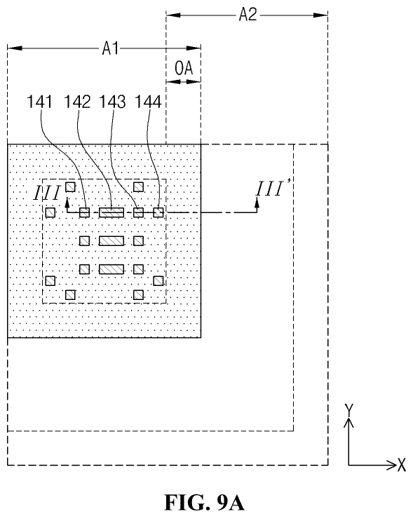

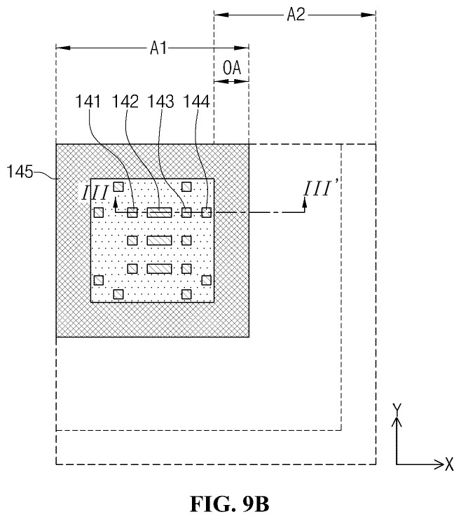

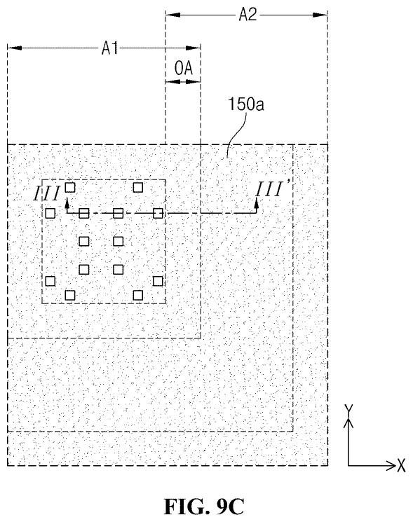

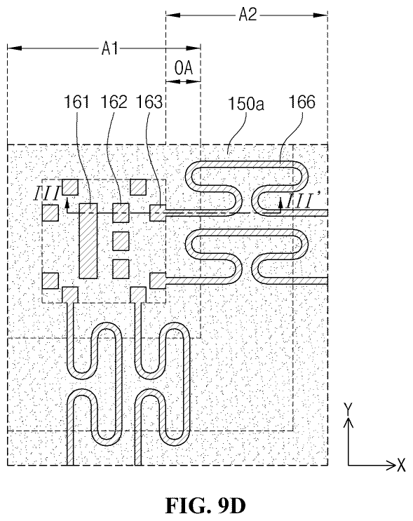

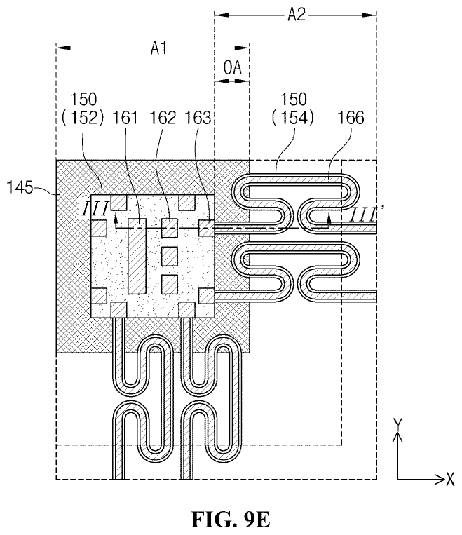

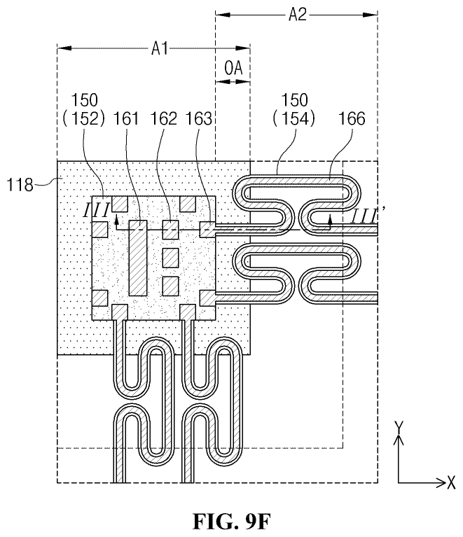

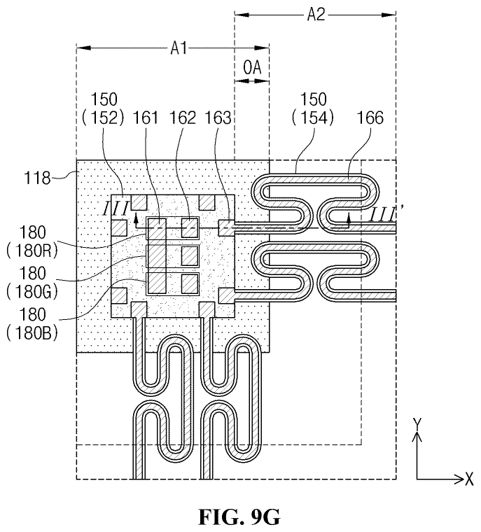

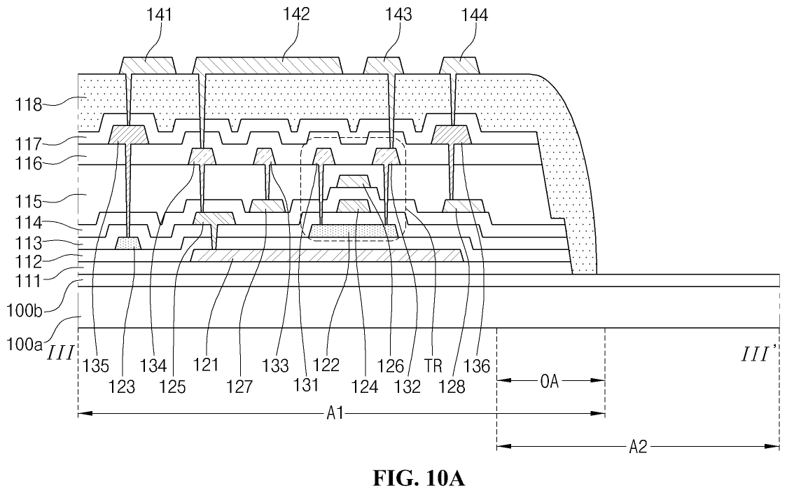

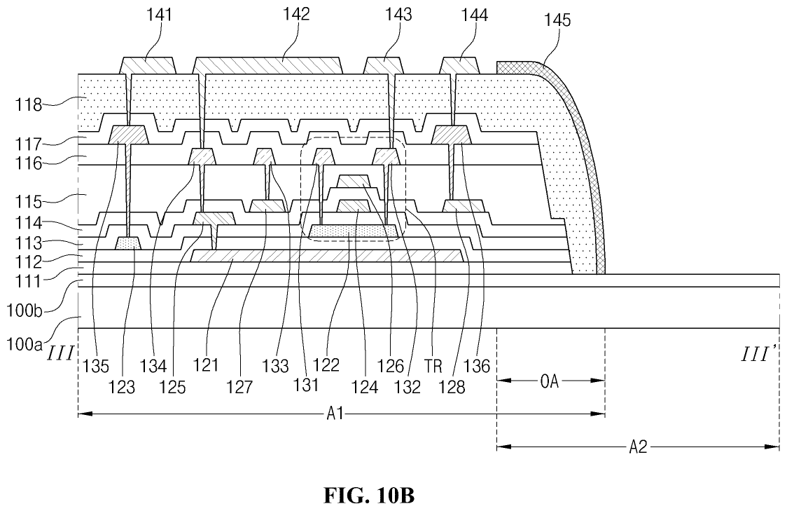

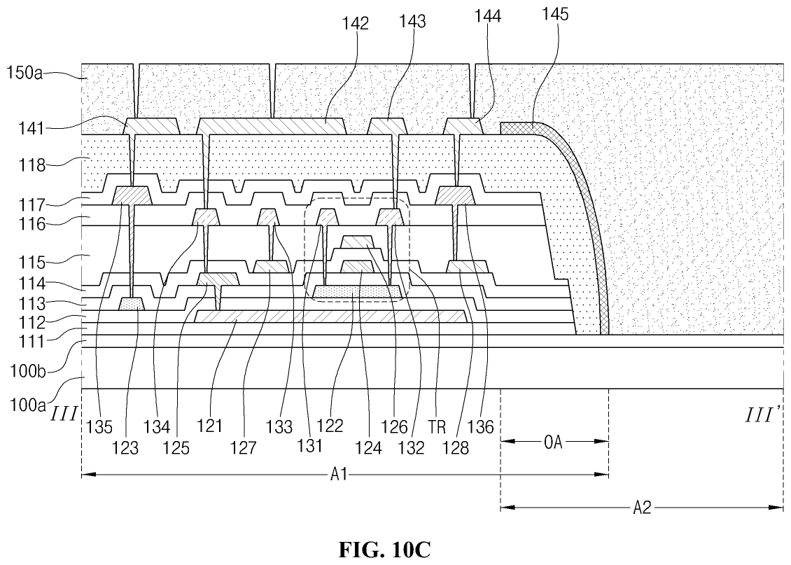

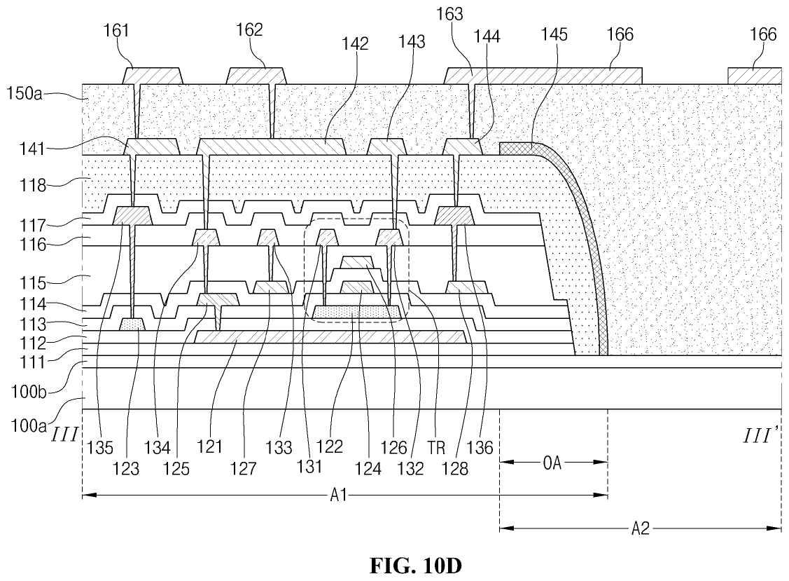

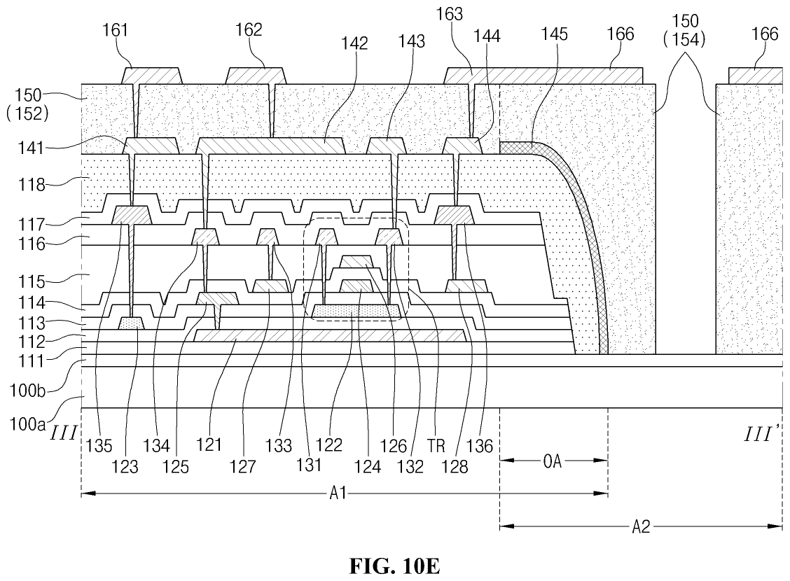

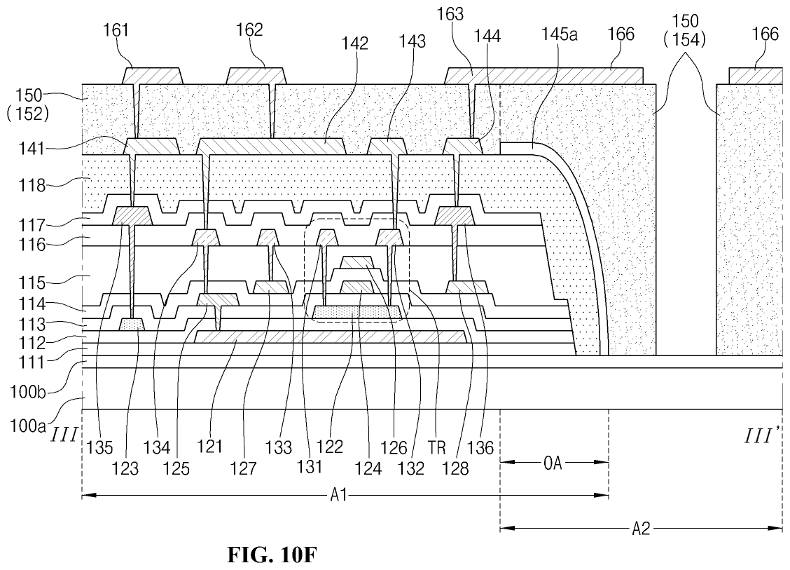

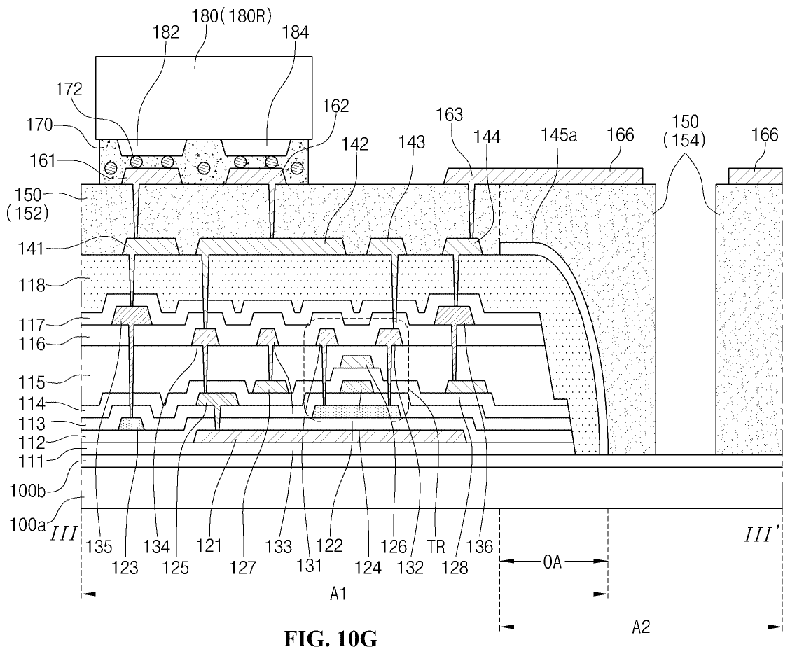

A method of manufacturing the stretchable display device according to the embodiments of the present disclosure will be described with reference to FIGS. 9A to 9G and FIGS. 10A to 10G.

FIGS. 9A to 9G are schematic plan views of the stretchable display device in steps of manufacturing the same according to the embodiments of the present disclosure. FIGS. 10A to 10G are schematic cross-sectional views of the stretchable display device in steps of manufacturing the same according to the embodiments of the present disclosure and show cross-sections corresponding to line III-III′ of FIGS. 9A to 9G, respectively.

Referring to FIG. 9A and FIG. 10A, a sacrificial layer 100b can be formed on a carrier substrate 100a provided with the rigid area A1 and the soft area A2. Here, the sacrificial layer 100b can be an inorganic layer and can be formed through a deposition process. For example, the sacrificial layer 100b can be formed by stacking amorphous silicon (a-Si) and silicon nitride (SiNx). In addition, the carrier substrate 100a can be formed of glass.

Then, the first buffer layer 11, the light blocking layer 121, and the second buffer layer 112 can be sequentially formed on the sacrificial layer 100b in the rigid area A1. After the semiconductor layer 122 and the semiconductor pattern 123 are formed on the second buffer layer 112, the gate insulation layer 113 can be formed. The gate electrode 124 and the first conductive pattern 125 can be formed on the gate insulation layer 113, and the first interlayer insulation layer 114 can be formed. The second, third, and fourth conductive patterns 126, 127, and 128 can be formed on the first interlayer insulation layer 114, and the second interlayer insulation layer 115 can be formed. The source electrode 131, the drain electrode 132, the fifth conductive pattern 133, and the sixth conductive pattern 134 can be formed on the second interlayer insulation layer 115, the third interlayer insulation layer 116 can be formed, and the seventh conductive pattern 135 and the eighth conductive pattern 136 can be formed. The passivation layer 117 and the planarization layer 118 can be sequentially formed on the seventh and eighth conductive patterns 135 and 136.

Here, the first and second buffer layers 111 and 112, the gate insulation layer 113, and the first interlayer insulation layer 114 can be removed together in the soft area A2 except for the overlap area OA and can be provided substantially in the rigid area A1. The second and third interlayer insulation layers 115 and 115 and the passivation layer 117 can be removed together in the soft area A2 except for the overlap area OA and can be provided substantially in the rigid area A1.

In addition, the planarization layer 118 can be removed in the soft area A2 except for the overlap area OA and can be provided substantially in the rigid area A1. Accordingly, a top surface of the sacrificial layer 100b can be exposed in the soft area A2 except for the overlap area OA. In the overlap area OA, the planarization layer 118 can cover and can be in contact with the side surfaces of the first and second buffer layers 111 and 112, the gate insulation layer 113, the first, second, and third interlayer insulation layers 114, 115, and 116, and the passivation layer 117.

Next, the first and second connection electrodes 141 and 142, the ninth conductive pattern 143, and the pad electrode 144 can be formed on the planarization layer 118 by depositing a conductive material and selectively removing it through a photolithography process. The first and second connection electrodes 141 and 142, the ninth conductive pattern 143, and the pad electrode 144 can be spaced apart from the soft area A2 and disposed in the rigid area A1. The first and second connection electrodes 141 and 142, the ninth conductive pattern 143, and the pad electrode 144 can also be spaced apart from the overlap area OA.

The first connection electrode 141 and the pad electrode 144 can be in contact with the seventh conductive pattern 135 and the eighth conductive pattern 136 through contact holes provided in the planarization layer 118 and the passivation layer 117, respectively. The second connection electrode 142 and the ninth conductive pattern 143 can be in contact with the sixth conductive pattern 134 and the drain electrode 132 through contact holes provided in the planarization layer 118, the passivation layer 117, and the third interlayer insulation layer 116, respectively.

Next, referring to FIG. 9B and FIG. 10B, a conductive material or an inorganic insulating material can be deposited on the first and second connection electrodes 141 and 142, the ninth conductive pattern 143, and the pad electrode 144 and can be selectively patterned through a photolithography process, thereby forming a dummy pattern 145 in the overlap area OA. The dummy pattern 145 can cover and be in contact with the top and side surfaces of the planarization layer 118 in the overlap area OA.

The dummy pattern 145 can be formed of a transparent conductive oxide. For example, the dummy pattern 145 can be formed of indium tin oxide (ITO) or indium zinc oxide (IZO).

Next, referring to FIG. 9C and FIG. 10C, an insulation material layer 150a can be formed on the first and second connection electrodes 141 and 142, the ninth conductive pattern 143, the pad electrode 144, and the dummy pattern 145 by applying an insulating material. The insulation material layer 150a can be selectively removed through a photolithography process, thereby forming a plurality of contact holes in the rigid area A1.

The insulation material layer 150a can be provided in both the rigid area A1 and the soft area A2. The contact holes of the insulation material layer 150a can expose the first connection electrode 141, the second connection electrode 142, and the pad electrode 144, respectively.

For example, the insulation material layer 150a can be formed of a polyimide (PI) resin or epoxy resin.

Next, referring to FIG. 9D and FIG. 10D, the first electrode 161, the second electrode 162, the auxiliary pad 163, and the stretchable line 166 can be formed on the insulation material layer 150a by depositing a conductive material and selectively patterning it through a photolithography process.

The first electrode 161, the second electrode 162, and the auxiliary pad 163 can be provided in the rigid area A1, and the stretchable line 166 can be provided in the soft area A2. In addition, the stretchable line 166 can also be provided in the overlap area OA of the rigid area A1 and the soft area A2. The first electrode 161, the second electrode 162, and the auxiliary pad 163 may not be provided in the overlap area OA.

The stretchable line 166 can have an omega structure including at least one omega shape. However, embodiments of the present disclosure are not limited thereto. In other embodiments, the stretchable line 166 can have a wave structure including at least one wave shape.

Next, referring to FIG. 9E and FIG. 10E, the protection layer 150 can be formed by selectively removing the insulation material layer 150a. The insulation material layer 150a can be removed substantially in the soft area A2 including the overlap area OA, and a top surface of the dummy pattern 145 can be exposed in the overlap area OA.

The insulation material layer 150a can be removed through a dry etch process. In this case, a mask pattern, which is used as a hard mask, can be provided on the protection layer 150. The mask pattern can be formed of a transparent conductive oxide such as indium tin oxide (ITO) or indium zinc oxide (IZO).

The protection layer 150 can include the first portion 152 and the second portion 154. The first portion 152 can be disposed in the rigid area A1 except for the overlap area OA, and the second portion 154 can be disposed in the soft area A2 including the overlap area OA. The second portion 154 of the protection layer 150 can be formed under the stretchable line 166 and can have substantially the same shape as the stretchable line 166. The width of the second portion 154 of the protection layer 150 can be greater than the width of the stretchable line 166.

Next, referring to FIG. 9F and FIG. 10F, the dummy pattern 145 of the overlap area OA can be removed. In this case, the dummy pattern 145 can be removed through a wet etch process.

In the overlap area OA, the gap or void 145a can be formed under the stretchable line 166, that is, between the planarization layer 118 and the second portion 154 of the protection layer 150. Accordingly, the stretchable line 166 and the second portion 154 of the protection layer 150 can be separated from the planarization layer 118 and stretched.

Next, referring to FIG. 9G and FIG. 10G, a transfer substrate provided with a transfer film can be provided over the carrier substrate 100a on which the void 145a is formed, and can be detached after applying heat and pressure, thereby forming the adhesive layer 170 on the first electrode 161 and the second electrode 162. The adhesive layer 170 can contain the plurality of conductive balls 172 therein.

Then, the light-emitting element 180 can be transferred on the adhesive layer 170, and heat and/or pressure can be applied to the light-emitting element 180, so that the first element electrode 182 and the second element electrode 184 can be electrically connected to the first electrode 161 and the second electrode 162, respectively. Here, the first element electrode 182 and the second element electrode 184 of the light-emitting element 180 can be in contact with the adhesive layer 170. The first element electrode 182 can be electrically connected to the first electrode 161 through the conductive balls 172 of the adhesive layer 170, and the second element electrode 184 can be electrically connected to the second electrode 162 through the conductive balls 172 of the adhesive layer 170.

Next, the carrier substrate 100a and the sacrificial layer 100b can be separated from the first buffer layer 111 and the protection layer 150. In this case, by irradiating a laser beam from the bottom of the carrier substrate 100a, the carrier substrate 100a and the sacrificial layer 100b can be separated. Then, the first adhesive layer 103 and the first substrate 101 of FIG. 7 and FIG. 8 can be attached on bottom surfaces of the first buffer layer 111 and the protection layer 150, and the second adhesive layer 108 and the second substrate 106 can be attached on top surfaces of the light-emitting element 180 and the stretchable line 166, thereby completing the display panel of the stretchable display device.

Alternatively, the second adhesive layer 108 and the second substrate 106 can be attached on the light-emitting element 180 and the stretchable line 166, the carrier substrate 100a and the sacrificial layer 100b can be separated, and the first adhesive layer 103 and the first substrate 101 can be attached.

As such, in the stretchable display device according to the embodiments of the present disclosure, the void 145a can be formed between the planarization layer 118 and the second portion 154 of the protection layer 150 in the overlap area OA using the dummy pattern 145, so that the stretchable line 166 can be separated from the rigid area A1.

In the stretchable display device according to aspects of the present disclosure, the rigid area and the soft area can be configured to partially overlap each other, and the distance between adjacent rigid areas can be decreased while maintaining the stretching properties, thereby increasing the resolution.

In addition, according to aspects of the present disclosure, by providing the stretchable line of the structure having relatively high stretching properties and repeated stretching reliability, the area of the soft area can be reduced, and the high resolution can be further realized, and by improving the lifetime due to the stretchable line, the production power consumption can be reduced to achieve the low power consumption.

It will be apparent to those skilled in the art that various modifications and variations can be made in the electroluminescent display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A stretchable display device comprising:
a substrate including a rigid area and a soft area;
a thin film transistor provided in the rigid area over the substrate;
a planarization layer provided over the thin film transistor;
a light-emitting element provided over the planarization layer, and the light-emitting element electrically connected to the thin film transistor; and
a stretchable line provided in the soft area over the substrate,
wherein the rigid area and the soft area partially overlap each other to thereby form an overlap area, and a distance between adjacent rigid areas is smaller than a length of the soft area.

2. The stretchable display device of claim 1, wherein a void is provided between the planarization layer and the stretchable line in the overlap area.

3. The stretchable display device of claim 2, further comprising a protection layer between the planarization layer and the stretchable line,
wherein the void is provided between the planarization layer and the protection layer.

4. The stretchable display device of claim 3, wherein the protection layer includes a first portion and a second portion, and
wherein the first portion of the protection layer corresponds to the rigid area except for the overlap area, and the second portion of the protection layer corresponds to the soft area including the overlap area.

5. The stretchable display device of claim 1, wherein the stretchable line includes a plurality of straight parts and a plurality of curved parts, and
wherein at least one of the plurality of straight parts is disposed in the overlap area.

6. The stretchable display device of claim 5, wherein the stretchable line has an omega structure including at least one omega shape.

7. The stretchable display device of claim 6, wherein the stretchable line includes a first straight part, a second straight part, and a third straight part and a first curved part and a second curved part, and
wherein the third straight part is disposed between the first straight part and the second straight part.

8. The stretchable display device of claim 7, wherein the first curved part is disposed between the first straight part and the third straight part, and the second curved part is disposed between the second straight part and the third straight part.

9. The stretchable display device of claim 7, wherein the second straight part is disposed in the overlap area.

10. The stretchable display device of claim 9, wherein at least one of the first and second curved parts is disposed in the overlap area.

11. The stretchable display device of claim 5, wherein the plurality of curved parts are not disposed in the overlap area.

12. The stretchable display device of claim 1, wherein the length of the soft area is equal to or smaller than a length of the rigid area.

13. The stretchable display device of claim 1, further comprising an auxiliary pad disposed in the rigid area and connected to one end of the stretchable line.

14. A method of manufacturing a stretchable display device, the method comprising:
preparing a carrier substrate, wherein a rigid area and a soft area are defined on the carrier substrate;
forming a thin film transistor in the rigid area over the carrier substrate;
forming a planarization layer over the thin film transistor of the rigid area;
forming a stretchable line in the soft area over the carrier substrate; and
transferring a light-emitting element over the planarization layer, wherein the light-emitting element is electrically connected to the thin film transistor,
wherein the rigid area and the soft area partially overlap each other to thereby form an overlap area, and a distance between adjacent rigid areas is smaller than a length of the soft area.

15. The method of claim 14, further comprising:
forming a protection layer between the planarization layer and the light-emitting element; and
forming a void between the planarization layer and the protection layer in the overlap area.

16. The method of claim 15, wherein the forming of the void includes:
forming a dummy pattern corresponding to the overlap area between the forming of the planarization layer and the forming of the protection layer; and
removing the dummy pattern after the protection layer is formed.

17. The method of claim 14, wherein the stretchable line includes a plurality of straight parts and a plurality of curved parts, and
wherein at least one of the plurality of straight parts is disposed in the overlap area.

18. The method of claim 14, wherein the length of the soft area is equal to or smaller than a length of the rigid area.
